(19) United States
(12) Patent Application Publication
(10) Pub. No.: US 2006/0121210 A1
(43) Pub. Date: Jun. 8, 2006

(54) Plasma processing equipment and method of operating the same

(76) Inventor: Jong-Jun Kim, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/283,971

(22) Filed: Nov. 22, 2005

(30) Foreign Application Priority Data
Dec. 3, 2004 (KR) 2004-101065

(51) Int. Cl. B08B 6/00; C23F 1/00; H05H 1/24; C23C 16/00

(52) U.S. Cl. 427/569; 156/345.38; 134/1.1; 118/723 R

(57) ABSTRACT

Plasma process equipment can enhance the plasma activation region during a process of cleaning the interior of the process chamber of the equipment so that polymer can be completely removed from the interior of the process chamber. The plasma processing equipment includes systems to supply a process gas into the process chamber and regulate the internal pressure of the process chamber, an electrostatic chuck disposed in the process chamber for supporting a wafer to be etched by plasma, a cathode disposed under the electrostatic chuck, a first high frequency power source connected to the cathode, a coil extending around the process chamber, a second high frequency power source connected to the coil, and a coil position altering mechanism for altering the position of a number of turns of the coil. After the wafer has been etched, the wafer is removed from the process chamber, and the position of the turns of the coil is changed to establish a plasma activation region in the chamber that is larger than that established during the etching process.

### BACKGROUND OF THE INVENTION

1. Field of the Invention

The present invention relates to plasma processing equipment used in the fabrication of semiconductor devices and the like. More particularly, the present invention relates to the cleaning of such plasma processing equipment.

2. Description of the Related Art

In general, a semiconductor device is fabricated by repeatedly subjecting a wafer to several processes such as cleaning, deposition, photoresist coating, exposure, development, etching, and ion implantation processes. Basically, the deposition process is preformed to form a layer on the wafer. The photoresist coating, exposure and development processes are performed to form a photoresist pattern on the layer. And, the etching process is performed to etch the layer using the photoresist pattern as a mask. The etched layer forms a circuit pattern, for example. Such an etching process may be classified as wet etching (an isotropic process) or dry etching (an anisotropic process).

Wet etching has been generally used to manufacture LSI (large scale integrated) devices whose circuit patterns have a minimum line width in a range of several hundreds to several tens of microns. On the other hand, wet etching is hardly ever used to fabricate VLSI (very large scale integrated) or ULSI (ultra large scale integrated) devices because of the limitations imposed by isotropic etching on achieving high degrees of integration. Hence, dry etching is generally used to fabricate today's highly integrated semiconductor devices.

In particular, a thin film on a wafer can be dry etched using plasma to form patterns whose critical dimensions are on the order of submicrons. The plasma is produced under a super high vacuum in a process chamber that is isolated from the atmosphere. Specifically, plasma is generated by exciting a process gas with a high frequency power. The process gas is selected so that the resulting plasma may undergo a strong chemical reaction with the specific layer targeted for etching. For instance, plasma can be produced to etch a silicon layer, a silicon nitride film, a polycrystalline silicon film, and a silicon oxide film when fabricating a semiconductor device.

FIG. 1 illustrates conventional plasma etching equipment for use in fabricating a semiconductor device.

The conventional etching equipment shown in FIG. 1 includes a process chamber 10 into which the process gas is supplied, and an electrostatic chuck 13 for supporting a wafer to be etched by plasma in the process chamber 10. The internal pressure of the process chamber can be regulated by a vacuum system (not shown) connected to the process chamber. Also, a cathode 12 is disposed in the process chamber, and is supplied with a first high frequency power of 13.56 MHz. A coil 11 is installed on the exterior of the process chamber, and is supplied with a second high frequency power of 12.56 MHz. Thus, a plasma activation region, in which the source gas is converted to plasma, is formed in the chamber 10 between the cathode 12 and the coil 11.

In the plasma etching equipment described above, a wafer is etched as follows.

Firstly, the wafer (not shown) is disposed on the electrostatic chuck 13, and then the process chamber 10 is supplied with the process gas, and the internal pressure of the process chamber is regulated. Next, the first high frequency power of 13.56 MHz is applied to the cathode 12, and the second high frequency power of 12.56 MHz is applied to the coil 11. As a result, electrons of the process gas are excited and collide with each other thereby forming ions at a high density, i.e., thereby forming a plasma, between the cathode 12 and the coil 11. The (ion) density of the plasma is measured, and the flow rate of the process gas and the internal pressure of the process chamber are regulated to maintain the plasma density constant.

In this process, the ions in the plasma activation region are attracted onto a surface of the wafer on the electrostatic chuck 13 by the first high frequency power applied to the cathode 12, and thereby etch the film on the surface of the wafer. However, in the etching of a wafer using the plasma, the etching rate and uniformity of the etching depend on several parameters of the process. That is, the plasma activation region is sensitive to the process conditions such as the internal pressure of the process chamber, the flow rate of the process gas, the applied voltage, and the like. These process conditions must be properly controlled to produce the desired etching rate and uniformity of the etching process.

The etching process produces by-products, such as a polymer, which adhere to inner wall surfaces of the chamber. If such polymer is allowed to accumulate it can flake off and thereby contaminate a wafer. Therefore, plasma is also used to clean the interior of the chamber 10 after the etching process has been completed. However, the coil 11 used to form the plasma is stationary. Therefore, as shown in FIG. 2, the plasma is created only in a limited region, i.e., the plasma activation region, in the process chamber during the cleaning process. Thus, the polymer is not completely removed from the inner walls of the process chamber during the cleaning process.

### SUMMARY OF THE INVENTION

Therefore, an object of the present invention is to provide plasma processing equipment in which potential contaminants, such as polymer, can be better removed from the interior of the process chamber of the equipment.

Likewise, another object of the present invention is to provide a method of operating plasma processing equipment such that potential contaminants produced during the plasma processing of a substrate are subsequently removed from the interior of the process chamber with a high degree of efficiency.

A more specific object of the present invention is to provide plasma processing equipment in which the plasma activation region can be enhanced during a process of cleaning the interior of the process chamber of the equipment.

Likewise, another object of the present invention is to provide a method of operating plasma processing equipment to enhance the plasma activation region during a process of cleaning the interior of the process chamber of the equipment

In accordance with one aspect of the present invention, the plasma processing equipment includes a process chamber, an electrostatic chuck and a cathode disposed in the process chamber, a coil extending around the process chamber, first and second high frequency power sources connected to the cathode and the coil, respectively, and a coil position altering mechanism for changing the position of a number of turns of the coil so that a plasma activation region throughout which plasma is created in the process chamber can be changed.

The coil position altering mechanism includes a coil holder that holds the turns of the coil, and a motor operatively connected to the coil holder so as to move the coil holder. Furthermore, a ball screw may connect the motor to the coil holder.

The coil holder comprises a plurality of brackets that hold the coil, and a connector by which the brackets are connected to one another. Each of the brackets has a first leg fixed relative to the process chamber, and a second leg that can be pivoted about the first leg. The turns of the coil are held by the second leg of each of the brackets.

According to another aspect of the present invention, a method of operating plasma processing equipment includes processing a substrate by transferring a substrate into a process chamber of the equipment and establishing a plasma activation region in a process chamber of the equipment, followed by a cleaning process in which the plasma activation region is enhanced. The processing of the substrate begins by transferring the substrate into the process chamber. Then, a process gas is supplied into the process chamber, and subsequently the process gas is excited in a plasma activation region in the process chamber to convert the gas into a plasma throughout the plasma activation region. The substrate is removed from the chamber after the substrate has been processed. The cleaning of the process chamber is then carried out by supplying a process gas into the process chamber, establishing a plasma activation region in the process chamber which is larger than the plasma activation region established while the substrate was being processed, and exciting the process gas in this larger, i.e., enhanced, plasma activation region.

The process gas is excited by applying a high frequency power to a coil having a number of turns extending around the process chamber. A high frequency power is also applied to a cathode disposed under the substrate during both the processing of the substrate and the cleaning of the process chamber. The plasma activation region is enhanced by moving the coil to change a position of the turns of the coil.

### BRIEF DESCRIPTION OF THE DRAWINGS

The above and other objects, features and advantages of the present invention will become more apparent from the following detailed description of the preferred embodiments thereof made with reference to the attached drawings in which:

FIG. 1 is a schematic diagram of conventional etching equipment for use in fabricating a semiconductor device;

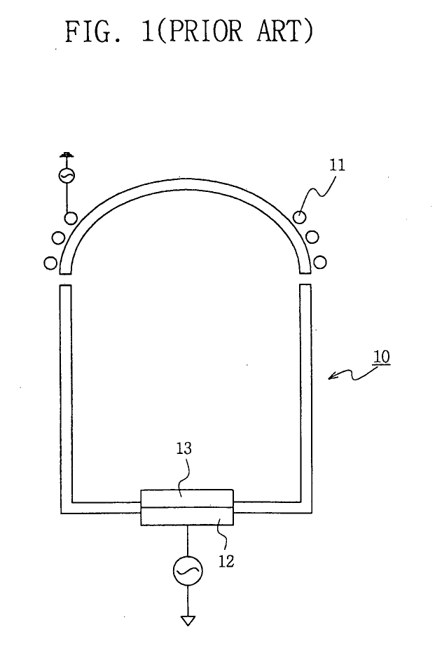

FIG. 2 is an enlarged view of the top portion of the conventional etching equipment showing the plasma activation region created when the equipment is operated;

FIG. 3 is a schematic diagram of plasma processing equipment according to the present invention;

FIG. 4 is a perspective view of the plasma processing equipment according to the present invention;

FIG. 5 is a sectional view of a portion of the plasma processing equipment shown in FIG. 4, illustrating a bracket of a coil holder; and

FIG. 6 is an enlarged view of the plasma processing equipment according to the present invention showing the plasma activation region created during a cleaning process.

### DETAILED DESCRIPTION OF THE PREFERED EMBODIMENTS

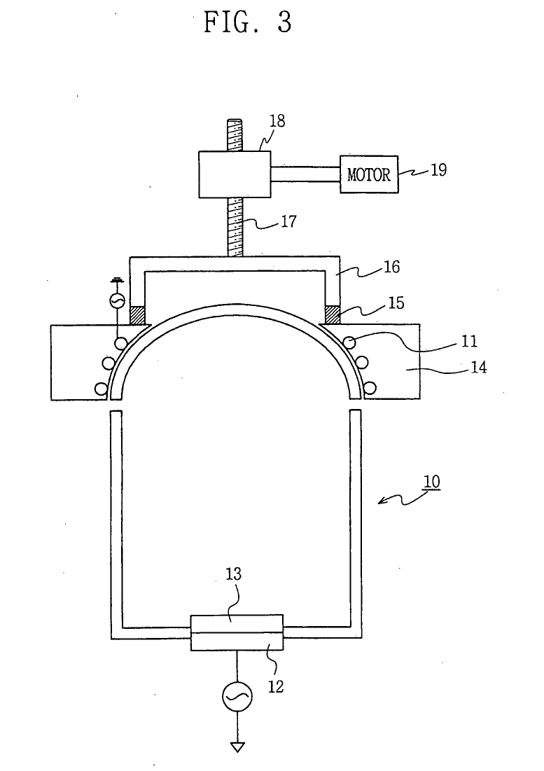

The present invention will now be described in detail with reference to FIGS. 3-6. In this respect, like reference numbers designate like elements throughout the drawings.

Referring first to FIG. 3, the plasma processing equipment includes a process chamber 10, a gas supply system (not shown) for supplying a process gas into the chamber 10, a vacuum system (not shown) connected to the chamber 10 for creating a vacuum in the chamber 10, an electrostatic chuck 13 disposed in the process chamber 10 for supporting a wafer to be processed by plasma, a cathode 12 disposed under the electrostatic chuck 13, a first high frequency power source connected to the cathode 12, a coil 11 extending around the process chamber 10, and a second high frequency power source connected to the coil 11. Thus, plasma is created in the chamber 10 in a plasma activation region between the cathode 12 and the coil 11 when a process gas is supplied into the chamber 10, and high frequency power is supplied to the cathode 12 and the coil 11.

In addition, the plasma processing equipment includes a coil position altering mechanism for altering the positions of a number of the turns of the coil 11. The coil position altering mechanism includes a coil holder to which the coil 11 is mounted, and a motor 19 connected to the coil holder. More specifically, the coil holder comprises a plurality of brackets 14 supporting the turns of the coil 11, and a connector 15 to which the brackets 14 are connected. The motor 19 may be a reversible motor. Also, a power transmission mechanism may be provided to transmit the output of the motor 19 to the coil holder. In particular, a plurality of rods 16 are connected to the connector 15 through respective ones of the brackets 14. The lead screw 17 of a ball screw is attached to a central portion of a plate from which the rods 16 extend. A guide 18 comprising the ball nut of the balls screw is held in place and can be rotated by the motor 19 for moving the lead screw 17 linearly up and down.

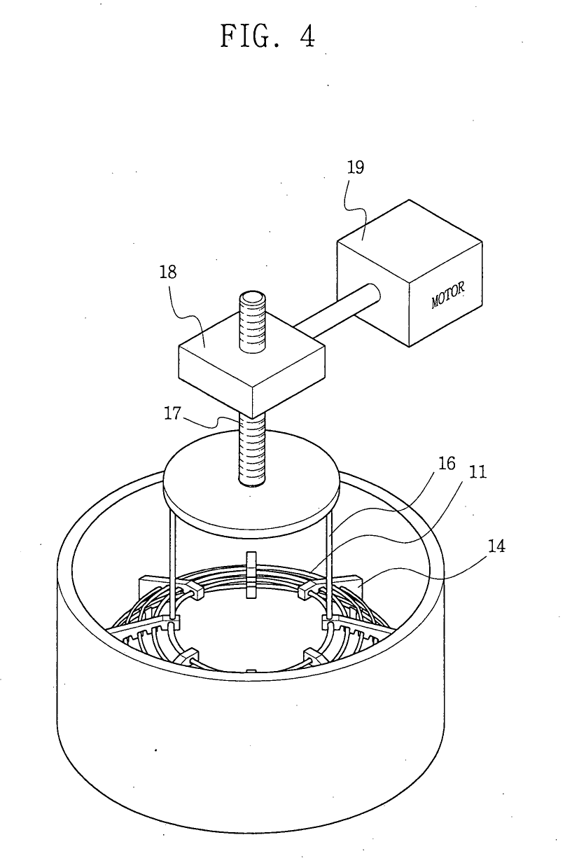

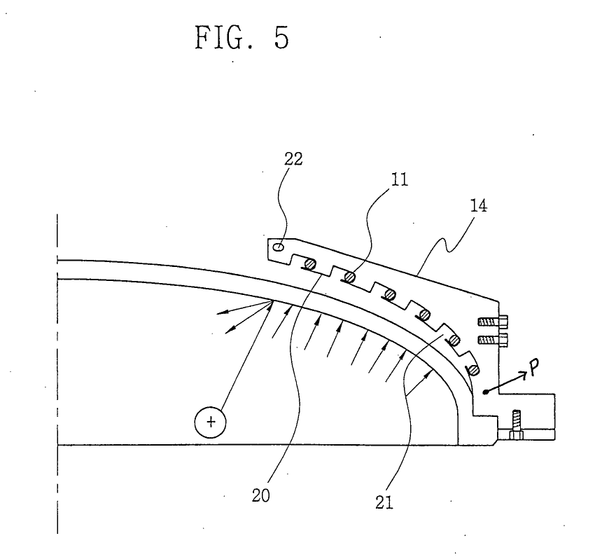

Referring now to FIGS. 4 and 5, the brackets 14 are spaced from one another at regular intervals around the coil 11. Also, each of the brackets 14 has first and second legs that form a right angle. The inner surface of the second leg of each bracket 14 that faces the process chamber 10 is a curved surface 20 that substantially conforms to the curvature of the upper (shield) portion of the process chamber 10. Recesses 21 are formed in the curved surface 20 as spaced apart at regular intervals and receive the turns of the coil 11, respectively. A hole 22 is formed in a free end of the second leg of the bracket 14 for receiving the connector 15. The first leg of the bracket is fixed to the process chamber. Thus, the brackets 14 can be flexed over a given range when the free ends of the brackets 14 are raised or lowered via the rods 16 and connector 15. Specifically, the second leg of each bracket 14 can be pivoted about a point P where the second leg joins the first leg. Thus, the turns of the coil 11 held by each bracket 14 lie generally along a line extending between the hole 22 in the bracket and the point P about which the bracket can be pivoted.

An operation of the plasma processing equipment according to the present invention will now be described with reference to FIGS. 3 through 6.

Firstly, a wafer (not shown) is disposed on the electrostatic chuck 13. Then, process gas is supplied into the process chamber 10 and the internal pressure of the process chamber is regulated.

At this time, the brackets 14 are held such that the turns of the coil 11 lie generally along a line (between hole 22 and point P) inclined at an angle of about 20 degrees with respect to the horizontal. Also, a first high frequency power of 1.8 to 2.17 MHz is applied to the cathode 12 and simultaneously, a second high frequency power of 13.56 MHz is applied to the coil 11. As a result, electrons of the process gas are excited, and collide with each other to create ions of a certain density. That is, plasma is produced in a plasma activation region between the cathode 12 and the coil 11. Once the plasma is created, the density of the plasma is measured by a plasma measuring device, and the flow rate of the process gas and the internal pressure of the process chamber are regulated to keep the plasma density constant. In addition, the ions in the plasma are guided onto a surface of the wafer on the electrostatic chuck 13 by the first high frequency power applied to the cathode 12, whereby a film on the surface of the wafer is etched.

The process chamber 10 is cleaned after the plasma etching process has been completed. At this time, the motor 19 is energized, and thus the lead screw 17 is lifted by the rotation of the ball nut of guide 18. As a result, the brackets 14 are flexed until the turns of the coil 11 generally lie along a line inclined at about 30 degrees relative to the horizontal.

Accordingly, the capacitance value of a circuit constituted by the coil 11 is changed. That is, the coil 11 is ground through capacitor banks (not shown) connected in parallel to form an LC circuit. The LC circuit resonates at a specific frequency, and a tuning point occurs near the specific resonant frequency of the LC circuit. The location of an RF tap is fixed, and the first high frequency power source finds a resonant condition of the plasma, with the first high frequency power being in a range of 1.8 MHz to 2.17 MHz.

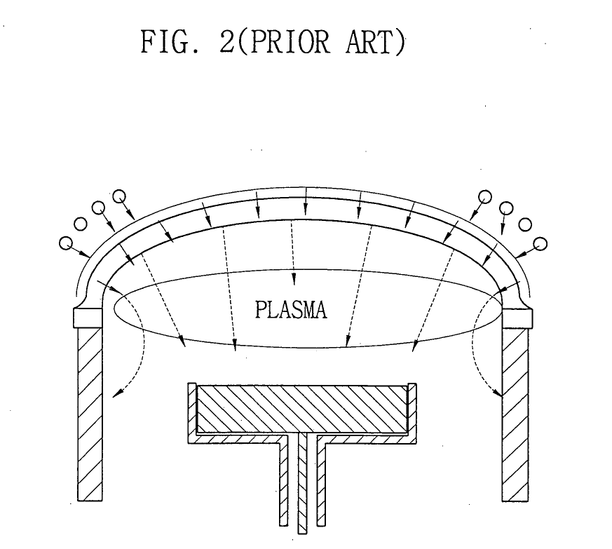

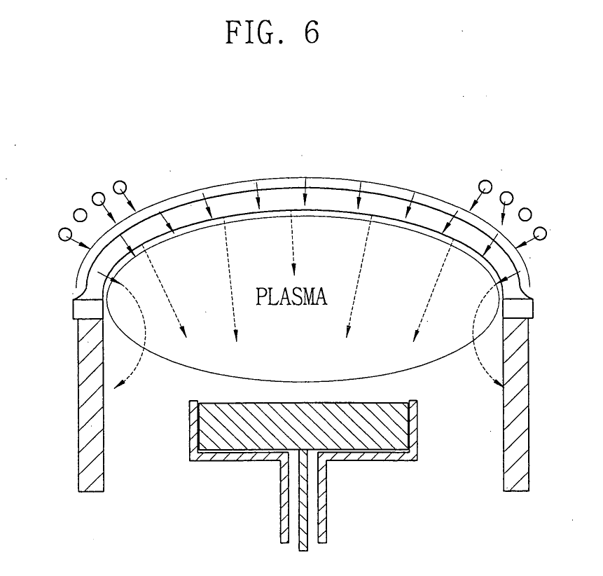

As a result, an enhanced plasma activation region is formed between the cathode 12 and the coil 11, as shown in FIG. 6. That is, the enhanced plasma activation region is larger than the plasma activation region established during the etching process shown in FIG. 2. In particular, the enhanced plasma activation region is established adjacent more of the inner wall surface of the process chamber. In the figures, the arrows formed by dashed lines show the directions of the electric force acting on positive charged particles.

After the plasma is created during the cleaning process, the density of the plasma density is measured by the plasma measuring device, and the flow rate of the process gas and the internal pressure of the process chamber are regulated to maintain the plasma density constant. Polymer on the inner wall surface of the process chamber 10 is removed by the plasma formed in the enhanced plasma activation region.

According to the present invention as described above, the position of the coil for creating the plasma is altered when the cleaning process is implemented, so that the plasma activation region is changed to better effect the removing of the polymer from the process chamber. In addition, the chamber can be cleaned in less time than if the same plasma activation region established during the etching process was implemented during the cleaning process. Accordingly, the present invention prevents the generation of particles and thus, decreases the number of defective products, i.e., increases the yield of the process.

Finally, the present invention has been described above in connection with the preferred embodiments thereof. However, the scope of the invention is not limited to the preferred embodiments. On the contrary, various modifications of and alternatives to the preferred embodiments will be apparent to those skilled in the art. Accordingly, the true spirit and scope of the invention is defined by the claims.

What is claimed is:

1. Plasma processing equipment comprising:
a process chamber;
an electrostatic chuck disposed in the process chamber so as to support a substrate to be processed by plasma in the chamber;
a cathode disposed in the process chamber;
a first high frequency power source connected to the cathode so as to apply a first high frequency power to the cathode;
a coil extending around the process chamber;
a second high frequency power source connected to the coil so as to apply a second high frequency power to the coil; and
a coil position altering mechanism including a coil holder that holds a number of turns of the coil, and a motor operatively connected to the coil holder so as to move the coil holder and thereby alter the position of said number of turns of the coil, whereby a plasma activation region throughout which plasma is created in the process chamber can be changed.

2. The plasma process equipment according to claim 1, wherein the coil holder comprises a plurality of brackets that hold the coil, and a connector connecting the brackets to one another.

3. The plasma process equipment according to claim 2, wherein the coil extends around an upper portion of the process chamber, each of the brackets has a first leg fixed relative to the process chamber, and a second leg that is pivotable about the first leg, said coil being held by the second leg of each of the brackets.

4. The plasma process equipment according to claim 3, wherein the second leg of each of the brackets has an inner surface facing the upper portion of the process chamber, and the inner surface of the second leg of each of the brackets defines a number of recesses in which said turns of the coil are received, respectively.

5. The plasma process equipment according to claim 1, wherein the coil position altering mechanism further includes a ball screw connecting said motor to the coil holder.

6. A method of operating plasma processing equipment comprising:
processing a substrate by transferring a substrate into a process chamber of the equipment, supplying a process gas into the process chamber, and subsequently exciting the process gas in a plasma activation region in the process chamber to convert the gas into a plasma throughout the plasma activation region;
removing the substrate from the chamber after the substrate has been processed; and
subsequently cleaning the process chamber by supplying a process gas into the process chamber, establishing an enhanced plasma activation region in the process chamber which is larger than the plasma activation region established in said processing of the substrate, and exciting the process gas in said enhanced plasma activation to convert the process gas into plasma throughout the enhanced plasma activation region.

7. The method of operating plasma processing equipment according to claim 6, wherein the exciting of the process gas in said processing of the substrate comprises applying a high frequency power to a coil having a number of turns extending around the process chamber, said establishing of the enhanced plasma activation region in said cleaning of the process chamber comprises moving the coil to change a position of said turns of the coil, and the exciting of the process gas in said cleaning of the process chamber comprises applying a high frequency power to the coil after the position of said turns of the coil has been changed.

8. The method of operating plasma processing equipment according to claim 7, wherein said processing of the substrate comprises applying a high frequency power to a cathode disposed under the substrate, and said establishing of the enhanced plasma activation region in said cleaning of the process chamber comprises applying a high frequency power to the cathode.
